(19) United States
(12) Patent Application Publication
(10) Pub. No.: US 2020/0373907 A1
(43) Pub. Date: Nov. 26, 2020

(54) TRANSVERSELY-EXCITED FILM BULK ACOUSTIC RESONATOR WITH MULTI-PITCH INTERDIGITAL TRANSDUCER

(71) Applicant: Resonant Inc., Goleta, CA (US)

(72) Inventor: Bryant Garcia, Burlingame, CA (US)

(21) Appl. No.: 16/989,699

(22) Filed: Aug. 10, 2020

Related U.S. Application Data
(63) Continuation-in-part of application No. 16/518,594, filed on Jul. 22, 2019, now Pat. No. 10,797,675.
Application No. 16/518,594 is a continuation-in-part of application No. 16/230,443, filed on Dec. 21, 2018, now Pat. No. 10,491,192.
Application No. 16/518,594 is a continuation-in-part of application No. 16/438,141, filed on Jun. 11, 2019, now Pat. No. 10,601,392.
Application No. 16/438,141 is a continuation-in-part of application No. 16/230,443, filed on Dec. 21, 2018, now Pat. No. 10,491,192.
(60) Provisional application No. 62/983,400, filed on Feb. 28, 2020.
(60) Provisional application No. 62/685,825, filed on Jun. 15, 2018.
(60) Provisional application No. 62/701,363, filed on Jul. 20, 2018.
(60) Provisional application No. 62/741,702, filed on Oct. 5, 2018.
(60) Provisional application No. 62/748,883, filed on Oct. 22, 2018.
(60) Provisional application No. 62/753,815, filed on Oct. 31, 2018.
(60) Provisional application No. 62/685,825, filed on Jun. 15, 2018.
(60) Provisional application No. 62/701,363, filed on Jul. 20, 2018.
(60) Provisional application No. 62/741,702, filed on Oct. 5, 2018.
(60) Provisional application No. 62/748,883, filed on Oct. 22, 2018.
(60) Provisional application No. 62/753,815, filed on Oct. 31, 2018.
(60) Provisional application No. 62/753,809, filed on Oct. 31, 2018.
(60) Provisional application No. 62/818,564, filed on Mar. 14, 2019.

(51) Int. Cl. H03H 9/13; H03H 9/54; H03H 9/17

(52) U.S. Cl. CPC H03H 9/13; H03H 9/17; H03H 9/54

(57) ABSTRACT

There are disclosed acoustic resonators and method of fabricating acoustic resonators. An acoustic resonator includes a single-crystal piezoelectric plate having front and back surfaces, the back surface attached to a surface of a substrate except for a portion of the piezoelectric plate forming a diaphragm spanning a cavity in the substrate. A conductor pattern on the front surface includes a multi-pitch interdigital transducer (IDT) with interleaved fingers of the IDT disposed on the diaphragm.

### RELATED APPLICATION INFORMATION

This patent claims priority from provisional patent application 62/983,400, filed Feb. 28, 2020, entitled VARIABLE PITCH XBAR FOR SPURIOUS SUPPRESSION.

This patent is also a continuation in part of application Ser. No. 16/518,594, filed Jul. 22, 2019, entitled TRANSVERSELY EXCITED FILM BULK ACOUSTIC RESONATOR USING ROTATED Z-CUT LITHIUM NIOBATE, which is a continuation-in-part of application Ser. No. 16/230,443, filed Dec. 21, 2018, titled TRANSVERSELY-EXCITED FILM BULK ACOUSTIC RESONATOR, now U.S. Pat. No. 10,491,192, which claims priority from the following provisional applications: application 62/685,825, filed Jun. 15, 2018, entitled SHEAR-MODE FBAR (XBAR); application 62/701,363, filed Jul. 20, 2018, entitled SHEAR-MODE FBAR (XBAR); application 62/741,702, filed Oct. 5, 2018, entitled 5 GHZ LATERALLY-EXCITED BULK WAVE RESONATOR (XBAR); application 62/748,883, filed Oct. 22, 2018, entitled SHEAR-MODE FILM BULK ACOUSTIC RESONATOR; and application 62/753,815, filed Oct. 31, 2018, entitled LITHIUM TANTALATE SHEAR-MODE FILM BULK ACOUSTIC RESONATOR. Application Ser. No. 16/518,594, is also a continuation-in-part of application Ser. No. 16/438,141, filed Jun. 11, 2019, titled SOLIDLY MOUNTED TRANSVERSELY-EXCITED FILM BULK ACOUSTIC RESONATOR, now U.S. Pat. No. 10,601,392, which is a continuation-in-part of application Ser. No. 16/230,443, filed Dec. 21, 2018, titled TRANSVERSELY-EXCITED FILM BULK ACOUSTIC RESONATOR, now U.S. Pat. No. 10,491,192, which claims the following provisional applications: application 62/685,825, filed Jun. 15, 2018, entitled SHEAR-MODE FBAR (XBAR); application 62/701,363, filed Jul. 20, 2018, entitled SHEAR-MODE FBAR (XBAR); application 62/741,702, filed Oct. 5, 2018, entitled 5 GHZ LATERALLY-EXCITED BULK WAVE RESONATOR (XBAR); application 62/748,883, filed Oct. 22, 2018, entitled SHEAR-MODE FILM BULK ACOUSTIC RESONATOR; and application 62/753,815, filed Oct. 31, 2018, entitled LITHIUM TANTALATE SHEAR-MODE FILM BULK ACOUSTIC RESONATOR. Application Ser. No. 16/438,141 also claims priority from provisional patent application 62/753,809, filed Oct. 31, 2018, titled SOLIDLY MOUNTED SHEAR-MODE FILM BULK ACOUSTIC RESONATOR, and provisional patent application 62/818,564, filed Mar. 14, 2019, titled SOLIDLY MOUNTED XBAR. All of these applications are incorporated herein by reference.

### NOTICE OF COPYRIGHTS AND TRADE DRESS

A portion of the disclosure of this patent document contains material which is subject to copyright protection. This patent document may show and/or describe matter which is or may become trade dress of the owner. The copyright and trade dress owner has no objection to the facsimile reproduction by anyone of the patent disclosure as it appears in the Patent and Trademark Office patent files or records, but otherwise reserves all copyright and trade dress rights whatsoever.

### BACKGROUND

### Field

This disclosure relates to radio frequency filters using acoustic wave resonators, and specifically to bandpass filters with high power capability for use in communications equipment.

### Description of the Related Art

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band depend on the specific application. For example, a “pass-band” may be defined as a frequency range where the insertion loss of a filter is less than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

RF filters typically require many design trade-offs to achieve, for each specific application, the best compromise between performance parameters such as insertion loss, rejection, isolation, power handling, linearity, size, and cost. Specific design and manufacturing methods and enhancements can benefit simultaneously one or several of these requirements.

Performance enhancements to the RF filters in a wireless system can have broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels.

High performance RF filters for present communication systems commonly incorporate acoustic wave resonators including surface acoustic wave (SAW) resonators, bulk acoustic wave (BAW) resonators, film bulk acoustic wave resonators (FBAR), and other types of acoustic resonators. However, these existing technologies are not well-suited for use at the higher frequencies proposed for future communications networks.

The desire for wider communication channel bandwidths will inevitably lead to the use of higher frequency communications bands. Radio access technology for mobile telephone networks has been standardized by the 3GPP (3^{rd} Generation Partnership Project). Radio access technology for 5^{th} generation mobile networks is defined in the 5G NR (new radio) standard. The 5G NR standard defines several new communications bands. Two of these new communications bands are n77, which uses the frequency range from 3300 MHz to 4200 MHz, and n79, which uses the frequency range from 4400 MHz to 5000 MHz. Both band n77 and band n79 use time-division duplexing (TDD), such that a communications device operating in band n77 and/or band n79 uses the same frequencies for both uplink and downlink transmissions. Bandpass filters for bands n77 and n79 must be capable of handling the transmit power of the communications device. The 5G NR standard also defines millimeter wave communication bands with frequencies between 24.25 GHz and 40 GHz.

### DESCRIPTION OF THE DRAWINGS

FIG. 1 includes a schematic plan view and two schematic cross-sectional views of a transversely-excited film bulk acoustic resonator (XBAR).

FIG. 2 is an expanded schematic cross-sectional view of a portion of the XBAR of FIG. 1.

FIG. 3 is an alternative expanded schematic cross-sectional view of an XBAR.

FIG. 4 is a graphic illustrating a shear horizontal acoustic mode in an XBAR.

FIG. 5 is a graph of the magnitude of admittance versus frequency for an XBAR with a conventional interdigital transducer (IDT).

FIG. 6 is an expanded portion of the graph of FIG. 5.

FIG. 7 is a plan view of a multi-pitch IDT.

FIG. 8 is a plan view of another multi-pitch IDT.

FIG. 9 is a graph of the magnitude of admittance versus frequency for an XBAR with a multi-pitch IDT.

FIG. 10 is an expanded portion of the graph of FIG. 8.

FIG. 11 is a graph of the input-output transfer function (S2,1) of a bandpass filter implemented using XBARs with multi-pitch IDTs.

Throughout this description, elements appearing in figures are assigned three-digit or four-digit reference designators, where the two least significant digits are specific to the element and the one or two most significant digit is the figure number where the element is first introduced. An element that is not described in conjunction with a figure may be presumed to have the same characteristics and function as a previously-described element having the same reference designator.

### DETAILED DESCRIPTION

Description of Apparatus

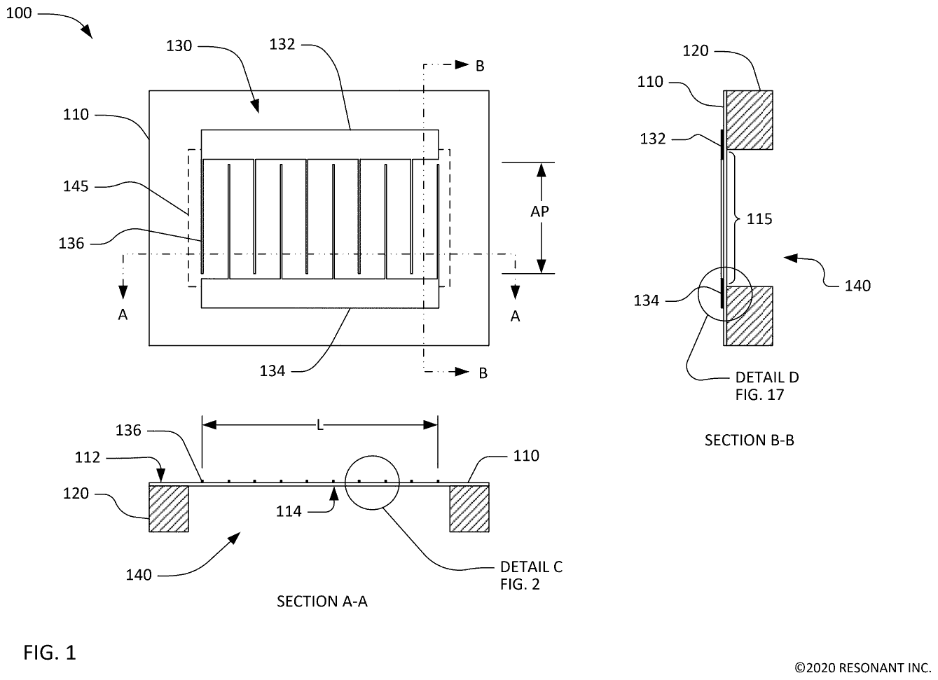

FIG. 1 shows a simplified schematic top view and orthogonal cross-sectional views of a transversely-excited film bulk acoustic resonator (XBAR) 100. XBAR resonators such as the resonator 100 may be used in a variety of RF filters including band-reject filters, band-pass filters, duplexers, and multiplexers. XBARs are particularly suited for use in filters for communications bands with frequencies above 3 GHz.

The XBAR 100 is made up of a thin film conductor pattern formed on a surface of a piezoelectric plate 110 having parallel front and back surfaces 112, 114, respectively. The piezoelectric plate is a thin single-crystal layer of a piezoelectric material such as lithium niobate, lithium tantalate, lanthanum gallium silicate, gallium nitride, or aluminum nitride. The piezoelectric plate is cut such that the orientation of the X, Y, and Z crystalline axes with respect to the front and back surfaces is known and consistent. In the examples presented in this patent, the piezoelectric plates are Z-cut, which is to say the Z axis is normal to the front and back surfaces 112, 114. However, XBARs may be fabricated on piezoelectric plates with other crystallographic orientations.

The back surface 114 of the piezoelectric plate 110 is attached to a surface of the substrate 120 except for a portion of the piezoelectric plate 110 that forms a diaphragm 115 spanning a cavity 140 formed in the substrate. The portion of the piezoelectric plate that spans the cavity is referred to herein as the “diaphragm” 115 due to its physical resemblance to the diaphragm of a microphone. As shown in FIG. 1, the diaphragm 115 is contiguous with the rest of the piezoelectric plate 110 around all of a perimeter 145 of the cavity 140. In this context, “contiguous” means “continuously connected without any intervening item”. In other configurations, the diaphragm 115 may be contiguous with the piezoelectric plate around at least 50% of the perimeter 145 of the cavity 140.

The substrate 120 provides mechanical support to the piezoelectric plate 110. The substrate 120 may be, for example, silicon, sapphire, quartz, or some other material or combination of materials. The back surface 114 of the piezoelectric plate 110 may be bonded to the substrate 120 using a wafer bonding process. Alternatively, the piezoelectric plate 110 may be grown on the substrate 120 or attached to the substrate in some other manner. The piezoelectric plate 110 may be attached directly to the substrate or may be attached to the substrate 120 via one or more intermediate material layers (not shown in FIG. 1).

“Cavity” has its conventional meaning of “an empty space within a solid body.” The cavity 140 may be a hole completely through the substrate 120 (as shown in Section A-A and Section B-B) or a recess in the substrate 120 under the diaphragm 115. The cavity 140 may be formed, for example, by selective etching of the substrate 120 before or after the piezoelectric plate 110 and the substrate 120 are attached.

The conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved. The interleaved fingers overlap for a distance AP, commonly referred to as the “aperture” of the IDT. The center-to-center distance L between the outermost fingers of the IDT 130 is the “length” of the IDT.

The first and second busbars 132, 134 serve as the terminals of the XBAR 100. A radio frequency or microwave signal applied between the two busbars 132, 134 of the IDT 130 excites a primary acoustic mode within the piezoelectric plate 110. As will be discussed in further detail, the primary acoustic mode is a bulk shear mode where acoustic energy propagates along a direction substantially orthogonal to the surface of the piezoelectric plate 110, which is also normal, or transverse, to the direction of the electric field created by the IDT fingers. Thus, the XBAR is considered a transversely-excited film bulk wave resonator.

The IDT 130 is positioned on the piezoelectric plate 110 such that at least the fingers of the IDT 130 are disposed on the diaphragm 115 of the piezoelectric plate which spans, or is suspended over, the cavity 140. As shown in FIG. 1, the cavity 140 has a rectangular shape with an extent greater than the aperture AP and length L of the IDT 130. A cavity of an XBAR may have a different shape, such as a regular or irregular polygon. The cavity of an XBAR may have more or fewer than four sides, which may be straight or curved.

For ease of presentation in FIG. 1, the geometric pitch and width of the IDT fingers is greatly exaggerated with respect to the length (dimension L) and aperture (dimension AP) of the XBAR. A typical XBAR has more than ten parallel fingers in the IDT 110. An XBAR may have hundreds of parallel fingers in the IDT 110. Similarly, the thickness of the fingers in the cross-sectional views is greatly exaggerated.

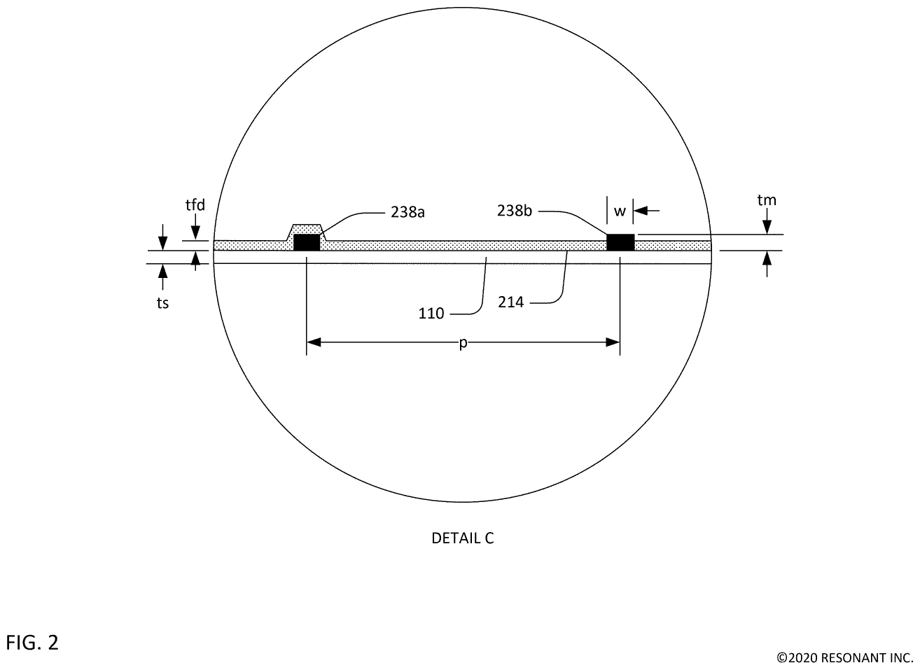

FIG. 2 shows a detailed schematic cross-sectional view of the XBAR 100. The piezoelectric plate 110 is a single-crystal layer of piezoelectrical material having a thickness ts. ts may be, for example, 100 nm to 1500 nm. When used in filters for LTE′ bands from 3.4 GHZ to 6 GHz (e.g. bands 42, 43, 46, n79, n77), the thickness ts may be, for example, 200 nm to 1000 nm.

A front-side dielectric layer 214 may optionally be formed on the front side of the piezoelectric plate 110. The “front side” of the XBAR is, by definition, the surface facing away from the substrate. The front-side dielectric layer 214 has a thickness tfd. The front-side dielectric layer 214 may be formed only between the IDT fingers (e.g. IDT finger 238b) or may be deposited as a blanket layer such that the dielectric layer is formed both between and over the IDT fingers (e.g. IDT finger 238a). The front-side dielectric layer 214 may be a non-piezoelectric dielectric material, such as silicon dioxide or silicon nitride. tfd may be, for example, 0 to 500 nm. tfd is typically less than the thickness ts of the piezoelectric plate. The front-side dielectric layer 214 may be formed of multiple layers of two or more materials.

The IDT fingers 238a and 238b may be aluminum, an aluminum alloy, copper, a copper alloy, beryllium, gold, tungsten, molybdenum or some other conductive material. The IDT fingers are considered to be “substantially aluminum” if they are formed from aluminum or an alloy comprising at least 50% aluminum. The IDT fingers are considered to be “substantially copper” if they are formed from copper or an alloy comprising at least 50% copper. Thin (relative to the total thickness of the conductors) layers of other metals, such as chromium or titanium, may be formed under and/or over and/or as layers within the fingers to improve adhesion between the fingers and the piezoelectric plate 110 and/or to passivate or encapsulate the fingers and/or to improve power handling. The busbars (132, 134 in FIG. 1) of the IDT may be made of the same or different materials as the fingers.

Dimension p is the center-to-center spacing or “pitch” of the IDT fingers, which may be referred to as the pitch of the IDT and/or the pitch of the XBAR. Dimension w is the width or “mark” of the IDT fingers. The geometry of the IDT of an XBAR differs substantially from the IDTs used in surface acoustic wave (SAW) resonators. In a SAW resonator, the pitch of the IDT is one-half of the acoustic wavelength at the resonance frequency. Additionally, the mark-to-pitch ratio of a SAW resonator IDT is typically close to 0.5 (i.e. the mark or finger width is about one-fourth of the acoustic wavelength at resonance). In an XBAR, the pitch p of the IDT is typically 2 to 20 times the width w of the fingers. In addition, the pitch p of the IDT is typically 2 to 20 times the thickness ts of the piezoelectric plate 110. The width of the IDT fingers in an XBAR is not constrained to be near one-fourth of the acoustic wavelength at resonance. For example, the width of XBAR IDT fingers may be 500 nm or greater, such that the IDT can be readily fabricated using optical lithography. The thickness tm of the IDT fingers may be from 100 nm to about equal to the width w. The thickness of the busbars (132, 134 in FIG. 1) of the IDT may be the same as, or greater than, the thickness tm of the IDT fingers.

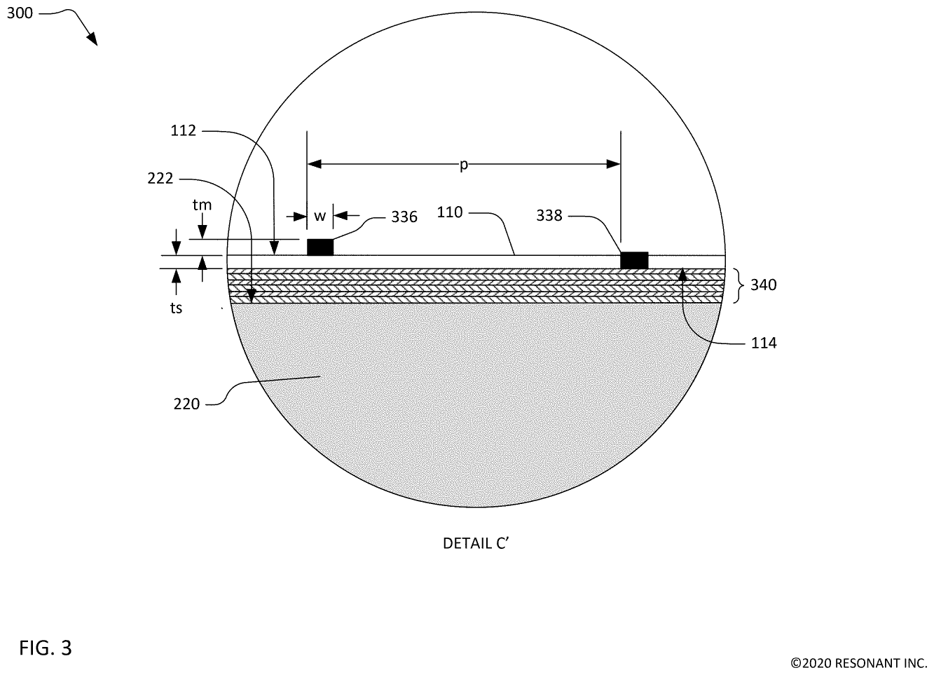

FIG. 3 shows a detailed schematic cross-sectional view of a solidly mounted XBAR (SM XBAR) 300. SM XBARs were first described in application Ser. No. 16/381,141. The SM XBAR 300 includes a piezoelectric plate 110, an IDT (of which only fingers 336 and 338 are visible). The piezoelectric layer 110 has parallel front and back surfaces 112, 114. Dimension ts is the thickness of the piezoelectric plate 110. The width of the IDT fingers 336, 338 is dimension w, thickness of the IDT fingers is dimension tm, and the IDT pitch is dimension p.

In contrast to the XBAR devices shown in FIG. 1 and FIG. 2, the IDT of an SM XBAR is not formed on a diaphragm spanning a cavity in the substrate 120. Instead, an acoustic Bragg reflector 340 is sandwiched between a surface 222 of the substrate 220 and the back surface 114 of the piezoelectric plate 110. The term “sandwiched” means the acoustic Bragg reflector 340 is both disposed between and mechanically attached to a surface 222 of the substrate 220 and the back surface 114 of the piezoelectric plate 110. In some circumstances, thin layers of additional materials may be disposed between the acoustic Bragg reflector 340 and the surface 222 of the substrate 220 and/or between the Bragg reflector 340 and the back surface 114 of the piezoelectric plate 110. Such additional material layers may be present, for example, to facilitate bonding the piezoelectric plate 110, the acoustic Bragg reflector 340, and the substrate 220.

The acoustic Bragg reflector 340 includes multiple dielectric layers that alternate between materials having high acoustic impedance and materials have low acoustic impedance. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As will be discussed subsequently, the primary acoustic mode in the piezoelectric plate of an XBAR is a shear bulk wave. Each of the layers of the acoustic Bragg reflector 340 has a thickness equal to, or about, one-fourth of the wavelength of a shear bulk wave having the same polarization as the primary acoustic mode at or near a resonance frequency of the SM XBAR 300. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 340 are not necessarily the same material, and all of the low acoustic impedance layers are not necessarily the same material. In the example of FIG. 3, the acoustic Bragg reflector 340 has a total of six layers. An acoustic Bragg reflector may have more than, or less than, six layers.

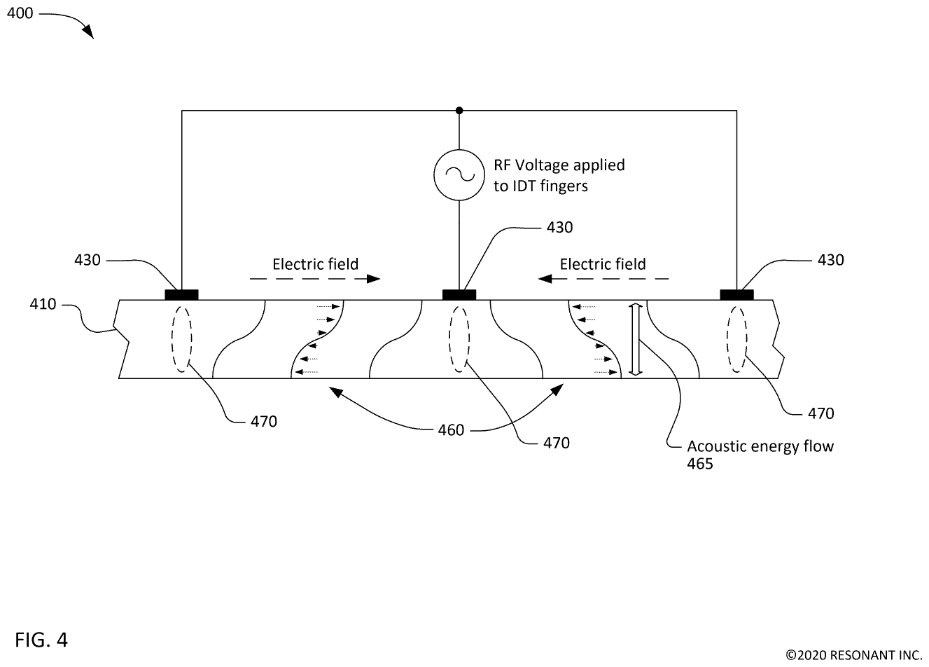

FIG. 4 is a graphical illustration of the primary acoustic mode of interest in an XBAR. FIG. 4 shows a small portion of an XBAR 400 including a piezoelectric plate 410 and three interleaved IDT fingers 430 which alternate in electrical polarity from finger to finger. An RF voltage is applied to the interleaved fingers 430. This voltage creates a time-varying electric field between the fingers. The direction of the electric field is predominantly lateral, or parallel to the surface of the piezoelectric plate 410, as indicated by the arrows labeled “electric field”. Due to the high dielectric constant of the piezoelectric plate, the RF electric energy is highly concentrated inside the plate relative to the air. The lateral electric field introduces shear deformation which couples strongly to a shear primary acoustic mode (at a resonance frequency defined by the acoustic cavity formed by the volume between the two surfaces of the piezoelectric plate) in the piezoelectric plate 410. In this context, “shear deformation” is defined as deformation in which parallel planes in a material remain predominantly parallel and maintain constant separation while translating (within their respective planes) relative to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and relative magnitude of atomic motion at the resonance frequency. The degree of atomic motion, as well as the thickness of the piezoelectric plate 410, have been greatly exaggerated for ease of visualization. While the atomic motions are predominantly lateral (i.e. horizontal as shown in FIG. 4), the direction of acoustic energy flow of the excited primary acoustic mode is substantially orthogonal to the surface of the piezoelectric plate, as indicated by the arrow 465.

Considering FIG. 4, there is essentially no RF electric field immediately under the IDT fingers 430, and thus acoustic modes are only minimally excited in the regions 470 under the fingers. There may be evanescent acoustic motions in these regions. Since acoustic vibrations are not excited under the IDT fingers 430, the acoustic energy coupled to the IDT fingers 430 is low (for example compared to the fingers of an IDT in a SAW resonator) for the primary acoustic mode, which minimizes viscous losses in the IDT fingers.

An acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. High piezoelectric coupling enables the design and implementation of microwave and millimeter-wave filters with appreciable bandwidth.

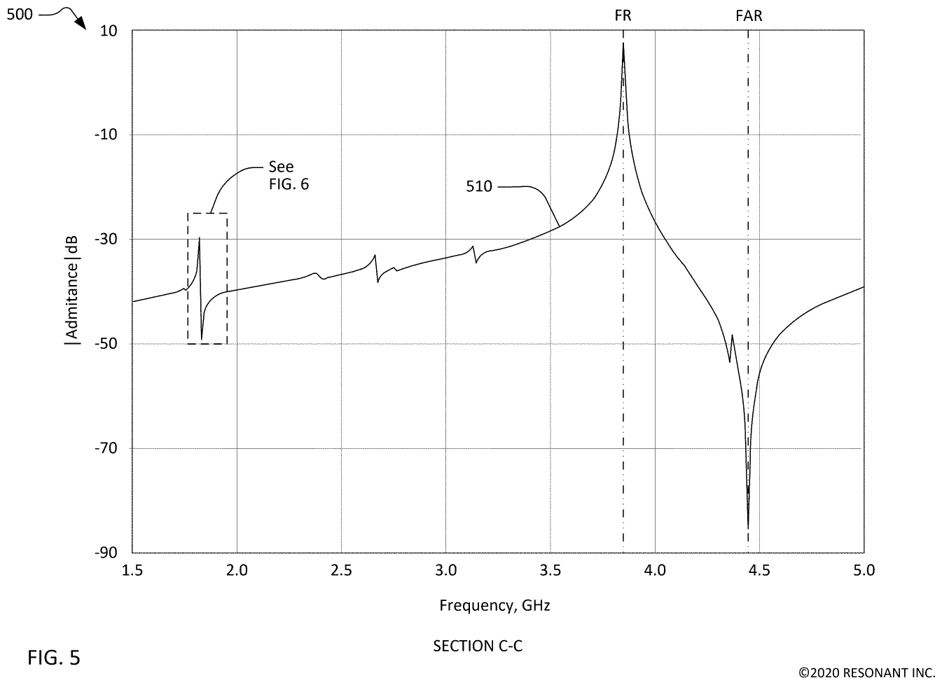

FIG. 5 is a graph 500 of the magnitude of admittance versus frequency for a first XBAR including a conventional (i.e. uniform pitch) IDT. The admittance was determined by simulation of the first XBAR using a finite element method. The line 510 is a plot of the magnitude of admittance. The shear primary acoustic mode of the first XBAR has an admittance maximum at a resonance frequency FR and an admittance minimum at an anti-resonance frequency FAR. The admittance plot 510 also exhibits multiple spurious modes or secondary resonances including a substantial spurious mode at a frequency about 1.825 GHz.

At least some of the spurious modes found in XBARs are traveling plate waves. The frequencies of traveling plate wave modes are proportional to IDT finger pitch. In contrast, the XBAR resonance and anti-resonance frequencies have only a slight dependence on IDT pitch. For example, changing IDT pitch from 7.5 times the piezoelectric plate thickness to 15 times (i.e. a 2:1 change) the piezoelectric plate thickness results in about 3% change in the resonance frequency of an XBAR.

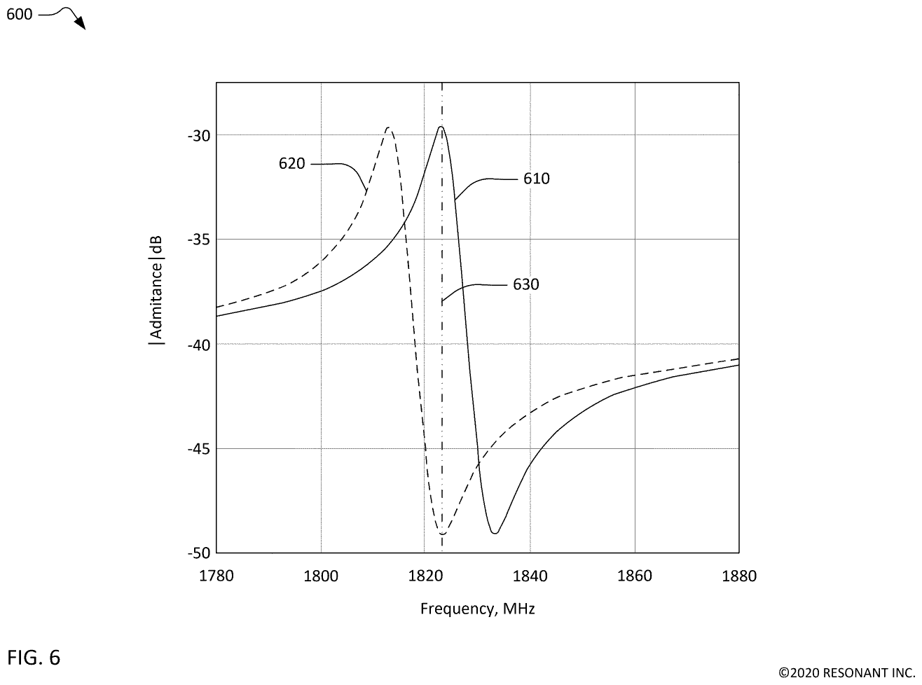

Slight variations in the pitch of the IDT in an XBAR can result in cancellation or destructive interference of spurious modes with negligible effect on the shear primary mode. This effect is illustrated in FIG. 6, which is an expanded view of a portion of the graph of FIG. 5 that contains the largest spurious mode. In FIG. 6, the solid curve 610 is a plot of the magnitude of admittance versus frequency for the XBAR with a conventional IDT, as previously shown in FIG. 5. The dashed curve 620 is a plot of the of the magnitude of admittance versus frequency of an XBAR with the IDT pitch increased by 0.5%. Increasing the IDT pitch by this amount lowers the frequency of the spurious mode by about 10 MHz, such that the admittance maximum of the curve 610 is aligned with the admittance minimum of the curve 620. If two resonators with these admittance characteristics were placed in parallel, the two spurious modes would, to at least some extent, cancel each other. Increasing the IDT pitch by 0.5% has a negligible effect on the resonance and anti-resonance frequencies of the shear primary acoustic mode of the XBAR.

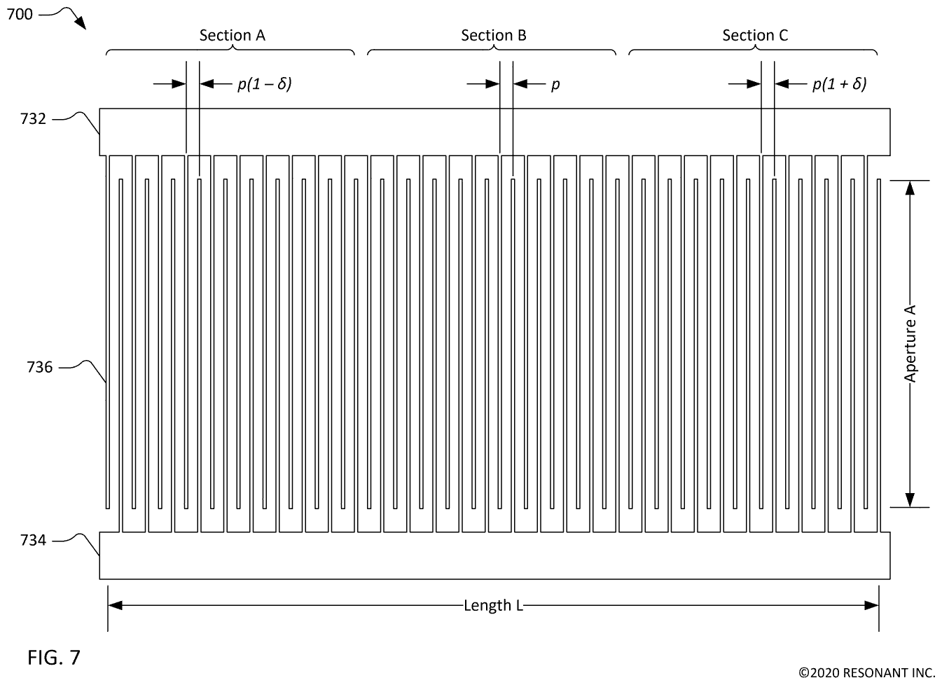

FIG. 7 is a plan view of an exemplary multi-pitch IDT 700. A “multi-pitch IDT” is an IDT where the pitch between the IDT fingers varies along the length of the IDT. At any given point along the length, the pitch does not vary across the aperture of the IDT. Further, the mark, or finger width, of a multi-pitch IDT is typically constant over the entire IDT.

The multi-pitch IDT 700 includes a first busbar 732, and a second busbar 734, and a plurality of interleaved fingers such as finger 736. The interleaved fingers extend alternately from the first and second busbars 732, 734. The multi-pitch IDT 700 is divided into three sections, identified and Section A, Section B, and Section C, along the length L of the IDT. Each of Sections A, B, and C includes 20 fingers, for a total of 60 fingers in the multi-pitch IDT 700. The use of three sections and 60 fingers is exemplary. An IDT may have more than or fewer than 60 total fingers. An IDT may be divided along its length into two or more sections, each of which includes a plurality of adjacent fingers. The total number of fingers may be divided essentially equally between the two or more sections. In this context, “essentially” means “as close as possible.” For example, an IDT with 100 fingers divided into three sections with 33, 34, and 33 fingers is considered to be divided essentially equally. The total number of fingers may be divided unequally between the two or more sections.

In this example, Section B has pitch p, which is the nominal pitch of the IDT. Section A has a pitch of p(1−δ), and Section C has a pitch of p(1+δ). δ is greater than 0 and less than or equal to 5%. δ may typically be less than 1%. δ may be selected during a filter design to achieve the most effective reduction of spurious modes. At any point along the length L of the IDT 700, the pitch is constant across the aperture A. The mark, or width of the IDT fingers is constant and the same in all sections. When an IDT is divided into two sections or more than three sections, the maximum pitch may be p(1+δ) and the minimum pitch may be p(1−δ).

In the example multi-pitch IDT 700, the pitch increases monotonically from left (as seen in the figure) to right. This is not necessarily the case in all multi-pitch IDTs. The sections of a multi-pitch IDT may be arranged in some other order. Further, in the multi-pitch IDT 700, the change in pitch between adjacent sections is constant. This is also not necessarily the case in all multi-pitch IDTs. The change in pitch between adjacent sections may be the same or different.

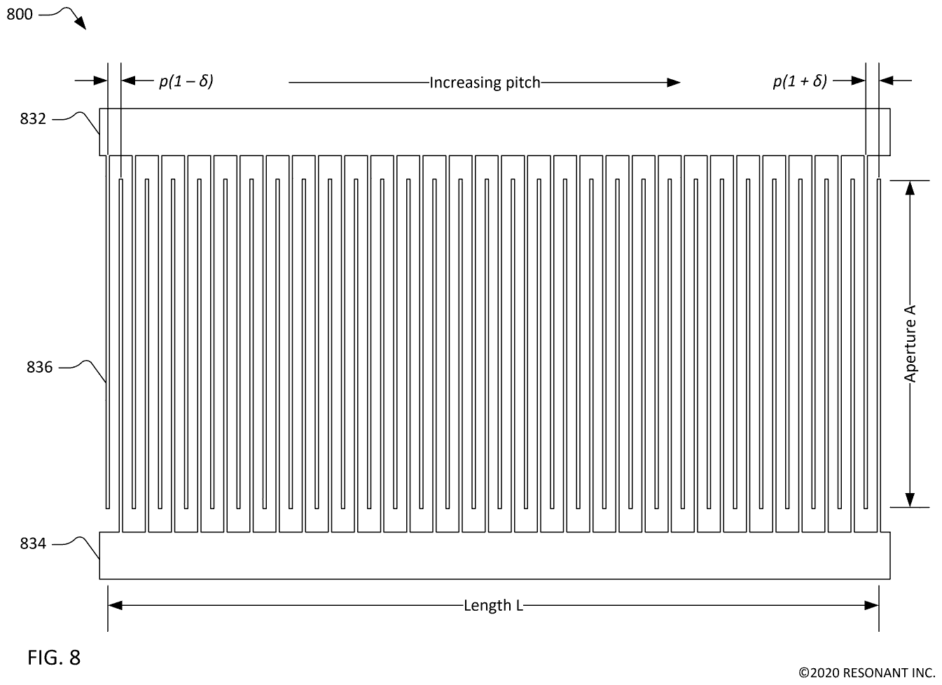

FIG. 8 is a plan view of another multi-pitch IDT 800 with continuously varying pitch. The IDT 800 includes a first busbar 832, and second busbar 834, and a plurality of interleaved fingers such as finger 836. The interleaved fingers extend alternately from the first and second busbars 832, 834. The IDT 800 is not divided into sections, but rather has a continuous change in pitch along it length L. The IDT 800 has 60 fingers, which is exemplary. An IDT may have more than or fewer than 60 total fingers.

As shown in FIG. 8, the pitch at the left edge of the IDT 800 is p(1−δ), and the pitch at the right edge of the IDT 800 is p(1+δ). The pitch varies continuously between these two extremes. The variation in pitch may typically, but not necessarily, be a linear function of position along the length L of the IDT. δ is greater than 0, less than or equal to 5%, and typically less than 1%. δ may be selected during a filter design to achieve the most effective reduction of spurious modes. At any point along the length of the IDT 800, the pitch is constant across the aperture A. The mark, or width of the IDT fingers is constant over the entire IDT.

The IDTs 700 and 800 may be incorporated into an XBAR as shown in FIG. 1 and FIG. 2 or an SM XBAR as shown in FIG. 3.

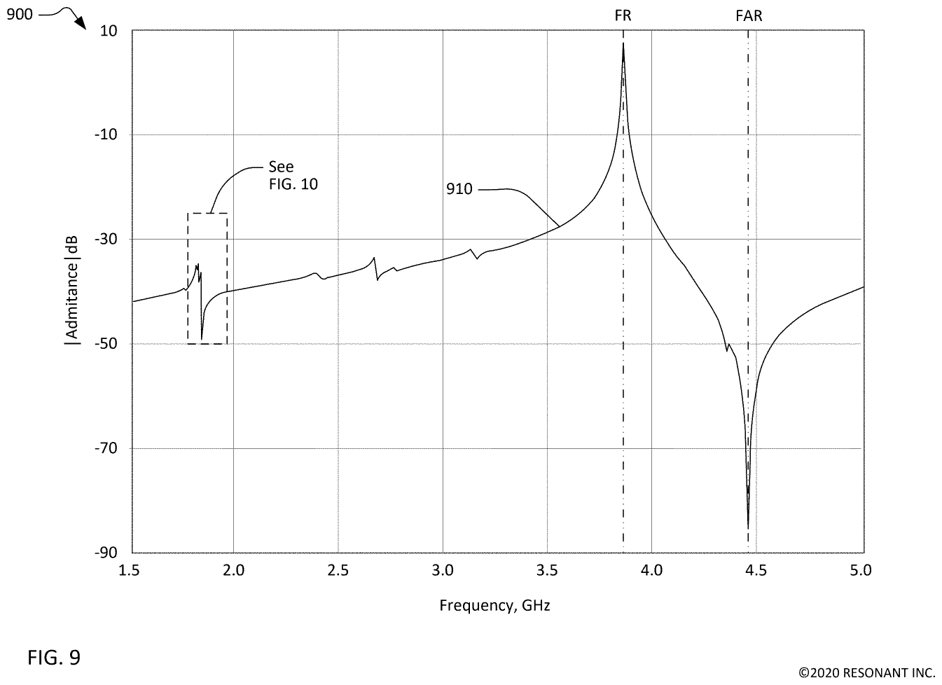

FIG. 9 is a graph 900 of the magnitude of admittance versus frequency for second XBAR including an IDT with varying pitch similar to the IDT 700 of FIG. 7. The IDT is divided along its length into three sections. The pitches of the three sections are 3.589, 3.6, and 3.611 microns (δ=0.3%). Other than the IDT pitch, the second XBAR is identical to the first XBAR having admittance characteristic previously shown in FIG. 5. The admittance was determined by simulation of the second XBAR using a finite element method. The line 910 is a plot of the magnitude of admittance of the second XBAR. The shear primary acoustic mode of the second XBAR has an admittance maximum at a resonance frequency FR and an admittance minimum at an anti-resonance frequency FAR. The resonance and anti-resonance frequencies are the same as those the XBAR with a uniform-pitch IDT. The admittance plot 910 also exhibits multiple spurious modes or secondary resonances. Comparison of FIG. 5 and FIG. 9 shows that the amplitudes of all of the spurious modes are reduced in the second XBAR due to the use of an IDT with varying pitch.

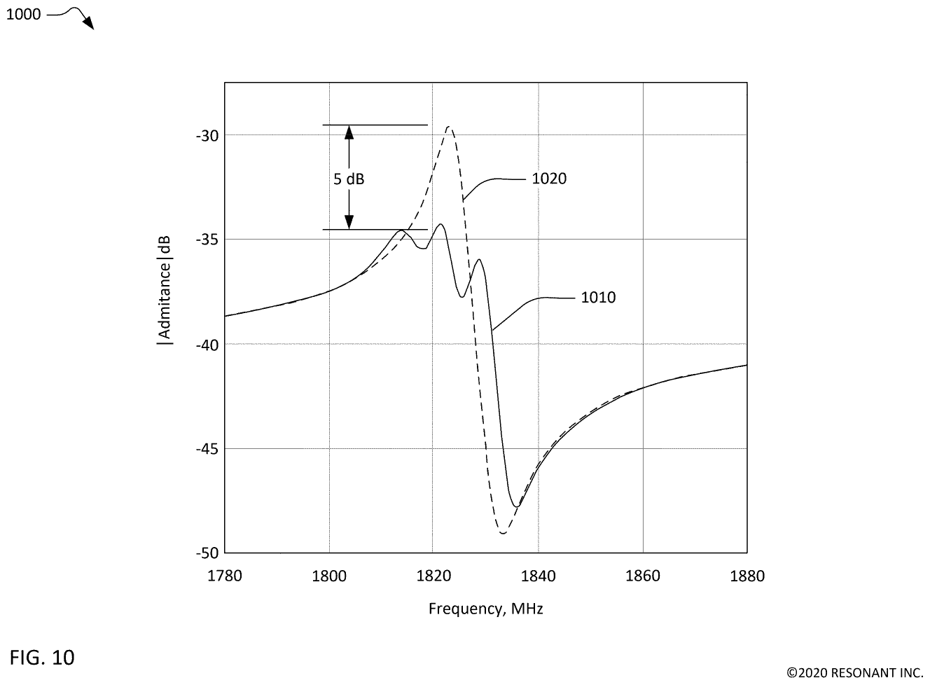

FIG. 10 shows an expanded portion of the graph of FIG. 9 that contains the largest spurious mode. In FIG. 10, the solid curve 1010 is a plot of the magnitude of admittance versus frequency for the XBAR including an IDT with varying pitch as shown in FIG. 9. The dashed curve 1020 is a plot of the of the magnitude of admittance versus frequency of an XBAR with a conventional uniform-pitch IDT, as previously shown in FIG. 6. The incorporation of a multi-pitch IDT reduces the peak of the spurious mode by almost 5 dB.

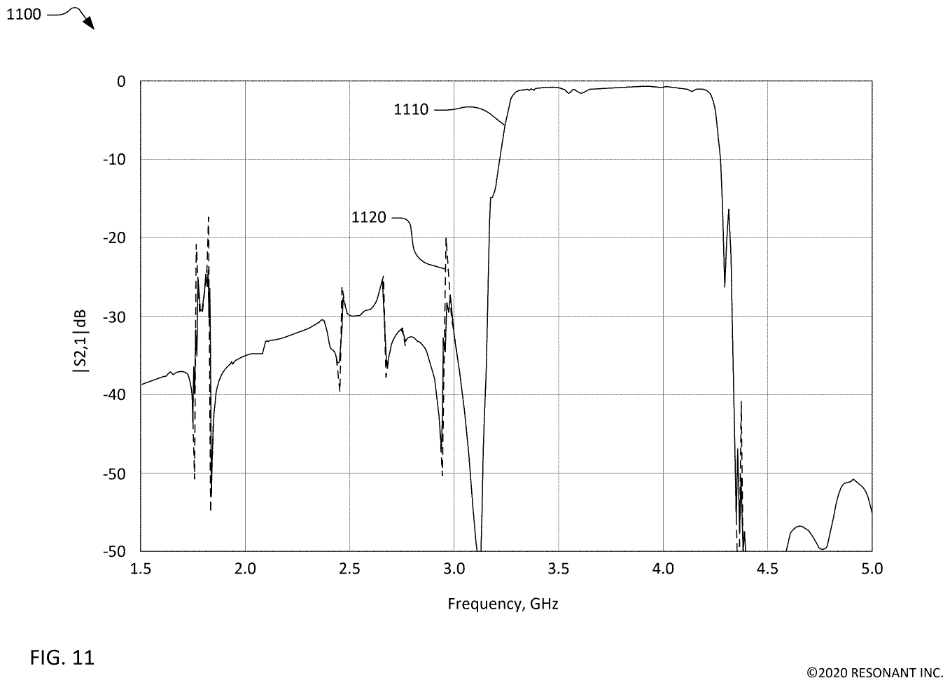

FIG. 11 is a graph of the magnitude of S2,1, the input/output transfer function, for two bandpass filters implemented with XBAR devices. The S2,1 data was determined by simulation of the two filters using a finite element method. The solid curve 1110 is a plot of S2,1 for a first filter using XBARs with multi-pitch IDTs. The first filter uses a ladder circuit with four series and four shunt resonators. Each resonator includes an IDT divided along its length into three equal sections as shown in FIG. 7. The parameter δ is 0.3% for series resonators and 0.4% for shunt resonators.

The dashed curve 1120 is a plot of S2,1 for a second bandpass filter that has uniform-pitch IDTs but is otherwise identical the first bandpass filter. Comparison of the curves 1110 and 1120 shows the passbands of the two filters are effectively the same. Compared to the second filter, the first filter with of multi-pitch IDTs exhibits reduced peak admittance of spurious modes by as much as 8 dB.

The filters used to generate the data shown in FIG. 11 are exemplary. A filter may have less than or more than five resonators, and more or less than three series resonator and two shunt resonators. Multi-pitch IDTs may be divided into two sections or more than three sections, or may be continuous. The number of sections may not be the same for all resonators in a filter, and a filter may include both sectioned and continuous multi-pitch IDTs. The value of δ may be different for some or all of the resonators. A filter may contain a combination of resonators with uniform pitch and multi-pitch resonators.

All of the examples discuss above were for conventional XBARs as shown in FIG. 1 and FIG. 2. Multi-pitch IDTs may also be used to reduce spurious modes in solidly-mounted XBARs as shown in FIG. 3. A similar reduction in spurious mode amplitude can be expected.

### CLOSING COMMENTS

Throughout this description, the embodiments and examples shown should be considered as exemplars, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

It is claimed:

1. An acoustic resonator, comprising:
a single-crystal piezoelectric plate having front and back surfaces, the back surface attached to a surface of a substrate, a portion of the piezoelectric plate forming a diaphragm spanning a cavity in the substrate;
a conductor pattern formed on the front surface, the conductor pattern comprising a multi-pitch interdigital transducer (IDT), interleaved fingers of the IDT disposed on the diaphragm.

2. The acoustic resonator of claim 1, wherein
the piezoelectric plate and the IDT are configured such that a radio frequency signal applied to the IDT excites a primary shear acoustic mode in the diaphragm.

3. The acoustic resonator of claim 1, wherein,
at any point along a length of the IDT, a pitch of the IDT is constant across an aperture of the IDT.

4. The acoustic resonator of claim 1, wherein
a mark of the IDT fingers is constant over the entire IDT.

5. The acoustic resonator of claim 1, wherein
the multi-pitch IDT is divided along its length into two or more sections, with each section having a respective pitch different from the pitch of each other section.

6. The acoustic resonator of claim 5, wherein
a maximum pitch of the multi-pitch IDT is p(1+δ) for one of the two or more sections, and
a minimum pitch of the multi-pitch IDT is p(1−δ) for another of the two or more sections,
where p is a nominal pitch and δ is greater than 0 and less than or equal to 5.0%.

7. The acoustic resonator of claim 6, wherein
δ is less than or equal to 1.0%.

8. The acoustic resonator of claim 6, wherein
the multi-pitch IDT is divided into three sections, and
the pitches of the three sections are p(1−δ), p, and p(1+δ), respectively.

9. The acoustic resonator of claim 1, wherein
a pitch of the multi-pitch IDT varies continuously along a length of the IDT.

10. The acoustic resonator of claim 8, wherein
the pitch of the multi-pitch IDT varies continuously between p(1−δ) and p(1+δ), where p is the nominal pitch of the IDT and δ is greater than 0 and less than or equal to 5.0%.

11. The acoustic resonator of claim 10, wherein
δ is less than or equal to 1.0%.

12. A filter device, comprising:
a single-crystal piezoelectric plate having front and back surfaces, the back surface attached to a surface of a substrate, portions of the piezoelectric plate forming a plurality of diaphragms spanning respective cavities in the substrate;
a conductor pattern formed on the front surface, the conductor pattern comprising a plurality of interdigital transducers (IDTs), interleaved fingers of the IDTs disposed on a respective one of a plurality of diaphragms,
wherein a first IDT from the plurality of IDTs is a multi-pitch IDT.

13. The filter device of claim 12, wherein
the piezoelectric plate and the plurality of IDTs are configured such that a respective radio frequency signal applied to each IDT excites a primary shear acoustic mode in the respective diaphragm.

14. The filter device of claim 12, wherein
all of the plurality of IDTs are multi-pitch IDTs.

15. The filter device of claim 12, wherein
the first IDT is divided along its length into two or more sections, with each section having a respective pitch different from the pitch of each other section.

16. The filter device of claim 15, wherein
a maximum pitch of the first IDT is p(1+δ) for one of the sections, and
a minimum pitch of the first IDT is p(1−δ) for another of the sections,
where p is a nominal pitch and δ is greater than 0 and less than or equal to 5.0%.

17. The filter device of claim 16, wherein
δ is less than or equal to 1.0%.

18. The filter device of claim 16, wherein
the first IDT is divided into three sections, and
the pitches of the three sections are p(1−δ), p, and p(1+δ), respectively.

19. The filter device of claim 12, wherein
a pitch of the first IDT varies continuously along a length of the first IDT.

20. The filter device of claim 19, wherein
the pitch of the first IDT varies continuously between p(1−δ) and p(1+δ), where p is the nominal pitch of the first IDT and δ is greater than 0 and less than or equal to 5%.

21. The filter device of claim 20, wherein
δ is less than or equal to 1.0%.

22. The filter device of claim 12, wherein a second IDT from the plurality of IDTs is a multi-pitch IDT, a variation in pitch of the second IDT being different from a variation in pitch of the first IDT.

23. The filter device of claim 22, wherein the second IDT is part of a shunt resonator and the first IDT is part of a series resonator.
